(19) United States
(12) Patent Application Publication
(10) Pub. No.: US 2012/0134090 A1
(43) Pub. Date: May 31, 2012

(54) SERVER COMPUTER SET

(75) Inventor: Sing-Hao PENG, Taipei City (TW)

(73) Assignee: INVENTEC CORPORATION, TAIPEI CITY (TW)

(21) Appl. No.: 13/084,514

(22) Filed: Apr. 11, 2011

(30) Foreign Application Priority Data
Nov. 30, 2010 (TW) 099141478

(51) Int. Cl. H05K 7/14

(52) U.S. Cl. 361/679.31

(57) ABSTRACT

This invention discloses a server computer set, which includes a power cabinet, at least one system cabinet, a first battery backup module and a second battery backup module. The power cabinet provides a high-voltage direct current (DC) power. The system cabinet includes a plurality of system units. The system cabinet shunts the high-voltage DC power to the system units. Each system unit includes a transformer and an internal circuit. The transformer is used for transforming the high-voltage DC power to a low-voltage DC power, which is used for driving the internal circuit. The first battery backup module is coupled between the power cabinet and the at least one system cabinet for providing a backup high-voltage DC power. The second battery backup module is disposed in the system units and coupled between the transformers and the internal circuits for providing a backup low-voltage DC power.

### RELATED APPLICATIONS

This application claims priority to Taiwan Application Serial Number 099141478, filed Nov. 30, 2010, which is herein incorporated by reference.

### BACKGROUND

1. Field of Invention

This invention relates to a power supply mechanism. More particularly, the disclosure relates to a power supply of a server computer set.

2. Description of Related Art

With the daily advance of computer industry, an enterprise more and more relies on an industrial computer system, wherein the industrial computer generally refers particularly to a non-personal computer or a non-consumer electronic system. For example, the industrial computer includes a core control device used for factory automation, a web server, an enterprise data backup server, etc.

With the development of electronic technologies and industrial computer-related applications, industry requirements for a server system are naturally increased accordingly. To meet the growth needs of enterprises, many enterprises typically integrate a large number of server units into a computer cabinet, and may combiner several groups of computer cabinets into a server computer set, so as to meet the demands of a large amount of data produced or high network flows, for example, and meanwhile to meet requirements of subsequent expansion and upgrade of the server system.

In the conventional art, an industrial computer machine table may include a plurality of system units, such as a multi-server or multi-storage computer system constructed by network application servers. If each system unit in a server computer set is disposed with a respective power supply and a respective power circuit, a large space will be occupied and it will be difficult to perform system maintenance. Therefore, most of the industrial computers use one single power device, and such a configuration can save the space and cost for installing devices therein. However, when the power device fails, the whole set of equipment will fail to operate.

For example, the industrial computer can be used as a core control device for factory automation, for example, a control core of a machine or a device such as a CNC control device, a CNC lathe or milling machine, etc., thereby providing functions for controlling, monitoring and testing a machine or instrument in a fabrication process. On the other hand, the industrial computer can be used as a data center of a financial institution for processing a large amount of data such as account information, transaction demands, account transfer authentication, etc.

Since the industrial computer is required to be directed to some specific devices or functions, it has to operate continuously and stably for a long time without interruption or crash, and thus the stability requirement for the computer system used therein is very strict. Therefore, most of the industrial computers are arranged with a backup system for data reservation (such as a disk array), so as to prevent an interruption or a crash in special conditions from occurring. However, a power system of the industrial computer often lacks a corresponding power backup device which is capable of providing a normal operation of the industrial computer system after a power device breaks down.

At present, some industrial computers may be equipped with a corresponding uninterruptible power supply (UPS). For example, a system power backup of an existing data center may adopt an alternating current UPS (AC-UPS). The AC-UPS still needs to be added with a direct current (DC) battery module externally, and the AC-UPS firstly converts an AC power to a DC power and stores the DC power in the DC battery module, thereby achieving the effect of backup power. When power from an electric power company is interrupted, the data center can store the data within a time period during which the DC battery module can provide power support. In addition, another backup electrical generator can also be actuated to provide a necessary DC power within the time period during which the DC battery module can provide power support.

Such an AC-UPS adopts a centralized backup power management, which has the defect that the related external DC battery module needs to be mounted near the cabinet of the uninterruptible power supply, thus requiring a considerable space. In general, the AC-UPS system is expensive in fabrication and huge in size, and thus it often takes a whole cabinet to dispose an expensive AC-UPS system. Thus, a whole server computer set may often share only one or two AC-UPS systems, and cannot achieve the object of providing an independent and distributed power backup for each system unit in an industrial computer.

### SUMMARY

In order to solve the above problems, this invention provides a server computer set, wherein a high-voltage direct current (DC) power is transferred directly between a power cabinet and a system cabinet of the server computer set. Therefore, a DC battery backup module can be used directly to provide a backup power. Thus, a step of converting an AC power into a DC power for backup can be omitted (in that step, an AC-DC converter needs to be disposed), and a step of converting the DC backup power back into the AC power for use can also be omitted (in that step, a DC-AC converter needs to be disposed). In addition, the battery backup module can be distributed to each system cabinet, without occupying a large space around the power cabinet. Moreover, in this invention, a first layer of battery backup unit is disposed between the power cabinet and the system cabinet, and a second layer of battery backup unit is additionally disposed in a system unit. The double-layer configuration of battery backup units can prolong effective backup time, and increase the availability of the backup power, and further improve the stability of the server computer set.

Therefore, an aspect of this invention is to provide a server computer set, which includes a power cabinet, at least one system cabinet, a first battery backup module and a second battery backup module. The power cabinet is coupled to an external power source for converting a high-voltage AC power supplied by the external power source into a high-voltage DC power. The at least one system cabinet is coupled to the power cabinet, wherein the system cabinet includes a plurality of system units, and the system cabinet shunts the high-voltage DC power to the system units. Each system unit includes a transformer and an internal circuit. The transformer is used for transforming the high-voltage DC power to a low-voltage DC power, and the low-voltage DC power is used for driving the internal circuit. The first battery backup module is coupled between the power cabinet and the system units for providing a backup high-voltage DC power. The second battery backup module includes a plurality of second battery backup units, and each of the second battery backup units is disposed in one of the system units and is coupled between the transformer and the internal circuit in the one of the system units for providing a backup low-voltage DC power.

According to an embodiment of this invention, the first battery backup module includes a lithium ion battery unit and/or a lead acid battery unit.

According to another embodiment of this invention, the second battery backup module includes a lithium ion battery unit.

According to yet another embodiment of this invention, the server computer set of this invention further includes a control module, and the control module is coupled respectively to the power cabinet, the first battery backup module and the second battery backup module. When the external power source is abnormal or the high-voltage DC power generated by the power cabinet is abnormal, the control module triggers the first battery backup module to supply the above backup high-voltage DC power. The first battery backup module stores a first electric quantity therein, and the first electric quantity corresponds to a first backup time.

Furthermore, after the above abnormal conditions occur and the first battery backup module has actuated the backup power for a time period, the control module can trigger the second battery backup module to supply the above backup low-voltage DC power when the first battery backup module has an insufficient electric quantity. The second battery backup module stores a second electric quantity therein, and the second electric quantity corresponds to a second backup time.

According to a further embodiment of this invention, the first battery backup module includes at least one first battery backup unit, and the at least one first battery backup unit is disposed between the power cabinet and the at least one system cabinet.

### BRIEF DESCRIPTION OF THE DRAWINGS

In order to make the foregoing as well as other aspects, features, advantages, and embodiments of this invention more apparent, the accompanying drawings are described as follows:

FIG. 1 is a schematic view of a server computer set according to an embodiment of this invention; and

FIG. 2 is a schematic view showing the server computer set of FIG. 1 and a control module.

### DETAILED DESCRIPTION

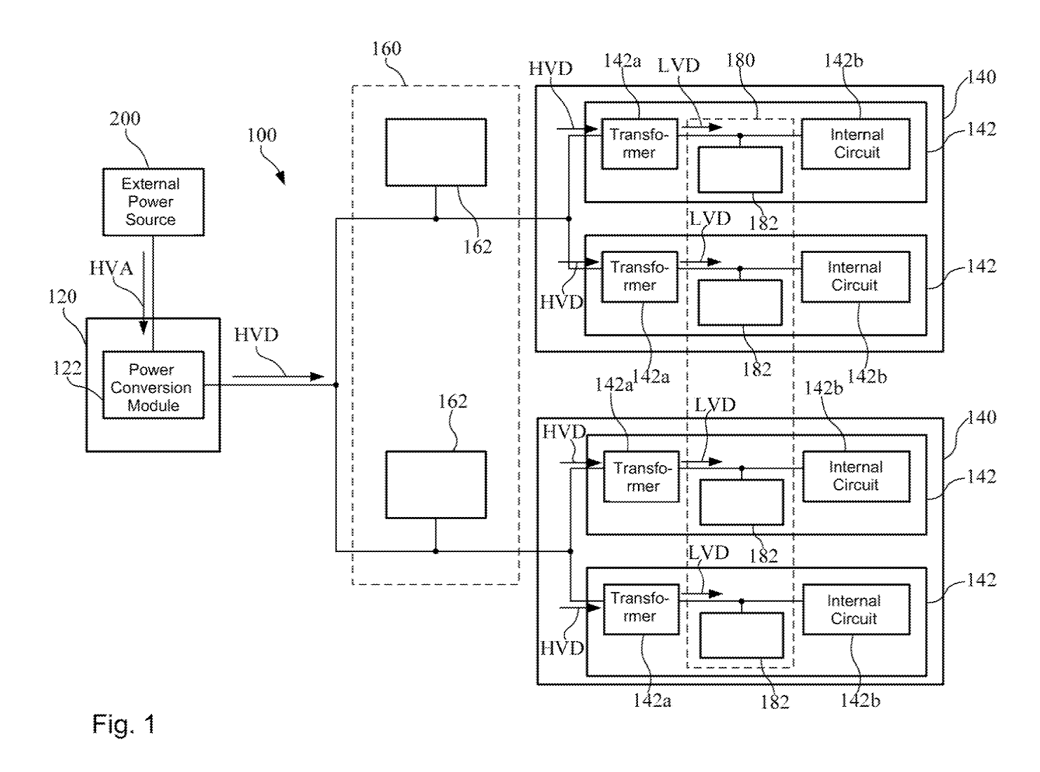

Referring to FIG. 1, FIG. 1 is a schematic view of a server computer set 100 according to an embodiment of this invention. As shown in FIG. 1, a server computer set 100 includes a power cabinet 120, at least one system cabinet 140, a first battery backup module 160 and a second battery backup module 180. In this embodiment, the power cabinet 120 can be used for supplying power to more than one system cabinet 140. Although only two system cabinets 140 are illustrated in the figure as an example, this invention is not limited to two system cabinets. For example, in some embodiments, the server computer set 100 used as a data center may include twelve system cabinets 140.

The power cabinet 120 functions as a main power supply source of the server computer set 100, and the power cabinet 120 may include a power conversion module 122 which can be coupled to an external power source 200 (such as a mains electricity source, a mains electricity socket or a mains electricity distributing board, etc). The external power source 200 is used for providing a high-voltage AC power (HVA) input, wherein the high-voltage AC power HVA is an AC power of higher than 300 V. For example, in this embodiment, the high-voltage AC power HVA can be a 380V AC power, and in an actual application, an electric power company itself can provide a 380V three-phase AC power.

In this embodiment, the power conversion module 122 of the power cabinet 120 is coupled to the external power source 200. The power conversion module 122 is used for converting the high-voltage AC power HVA into a high-voltage DC power HVD, and in this embodiment, the high-voltage DC power HVD can be 380V DC power.

Each system cabinet 140 includes a plurality of system units 142. In FIG. 1, for brief illustration, the system cabinet 140 also includes two system units 142 as an example for explanation, but this invention is not limited thereto. In an actual application, the system cabinet 140 may include from several to hundreds of system units 142 in accordance with actual requirements.

As for each system cabinet 140, the system cabinet 140 can shunt the high-voltage DC power HVD from the power conversion module 122 of the power cabinet 120 to each system unit 142.

As for each system unit 142 in the system cabinet 140, the system unit 142 includes a transformer 142a and an internal circuit 142b, and the transformer 142a is coupled to the internal circuit 142b. The transformer 142a is used for transforming the inputted high-voltage DC power HVD (e.g. 380V DC) to a low-voltage DC power LVD (e.g. 12V DC), and the low-voltage DC power LVD is used for driving the internal circuit 142b.

It should be pointed out particularly that, in the server computer set 100 of this invention, the power cabinet 120 directly converts the inputted AC power into a DC power, and directly distributes the power to each system unit 142 of the system cabinet 140 in a DC power form, which is different from a power distribution in an AC power form in the conventional art. Using the DC power form to distribute power facilitates the disposing of a power backup module. The server computer set 100 of this invention can directly use DC battery backup modules 160 and 180 to provide a backup power. Compared with a conventional method, a step of converting an AC power into a DC power for backup can be omitted (in that step, an AC-DC converter needs to be disposed), and a step of converting the DC backup power back into the AC power for use can also be omitted (in that step, a DC-AC converter needs to be disposed). In addition, the battery backup modules 160 and 180 can be distributed to each system cabinet 140, without occupying a large space around the power cabinet 120.

That is to say, the server computer set 100 of this invention can avoid disposing an AC-DC converter wherever a power backup system needs to be disposed. Therefore, for the case of many system cabinets, the cost of disposing a large number of AC-DC converters can be saved.

The following paragraphs will describe a mechanism for providing a backup power by using the first battery backup module 160 and the second battery backup module 180 in the server computer set 100 of this invention. As shown in the figure, in this embodiment, the first battery backup module 160 includes plural first battery backup units (BBUs) 162, and the first BBUs 162 are disposed respectively between the power cabinet 120 and the system cabinets 140. In this embodiment, the first battery backup module 160 totally includes two first battery backup units 162 respectively corresponding to the two system cabinets 140. Each first battery backup unit 162 may be a lithium ion battery unit or a lead acid battery unit, which can be used for storing the high-voltage DC power HVD from the power cabinet 120.

Moreover, the second battery backup module 180 includes plural second battery backup units (BBUs) 182 each of which is disposed in one of the system units 142 and is coupled between the transformer 142a and the internal circuit 142b in the one of the system units, i.e. the second BBUs 182 are disposed respectively between the transformers 142a and the internal circuits 142b. In this embodiment, the second battery backup module 180 totally includes four second battery backup units 182 respectively corresponding to the four system units, but this invention is not limited thereto. Each second battery backup unit 182 can be a lithium ion battery unit used for storing the low-voltage DC power LVD from the transformers 142a.

When the external power source 200 is abnormal or the high-voltage DC power. HVD generated by the power cabinet 120 is abnormal and the first battery backup module 160 detects that the high-voltage DC power HVD is abnormal (e.g. too low), the first battery backup module 160 can generate and provide a backup high-voltage DC power to drive the system cabinets 140 to operate normally or perform a function of emergency data reservation.

In an actual application, the first battery backup module 160 stores a specific first electric quantity therein, which can correspond to a first backup time depending on the first electric quantity of the first battery backup module 160 and a power consumption level of the system cabinets 140. When an abnormal condition lasts longer than the first backup time, the electric quantity of the first battery backup module 160 may be insufficient to drive the system cabinets 140 to operate normally.

When the high-voltage DC power HVD generated by the power cabinet 120 is abnormal and the first battery backup module 160 has an insufficient backup electric quantity, the second battery backup module 180 can generate a backup low-voltage DC power and supply it to the internal circuits in the system cabinets 140 for use. In an actual application, a triggering control signal for triggering the second battery backup module 180 to generate the backup low-voltage DC power can be provided by the transformers 142a (or a power supply device).

Through the above double-layer backup architecture (the first battery backup module 160 and the second battery backup module 180), the first backup time and the second backup time can be aggregated, thereby forming a longer backup time equivalently. In addition, an availability of the backup power is increased, thereby improving a stability of the server computer set 100.

Moreover, the server computer set 100 may further include a control module, and the control module can be used for triggering and controlling an action and a time point of the first battery backup module 160 and the second battery backup module 180 for providing the backup power.

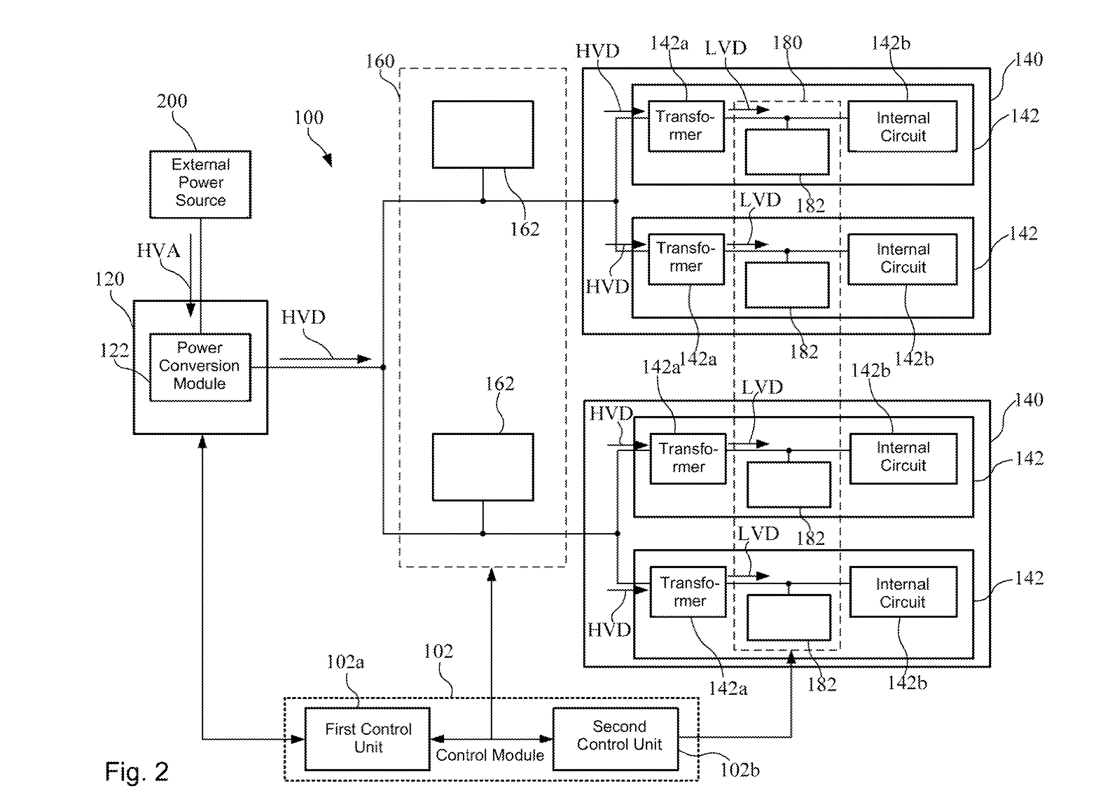

Referring also to FIG. 2, FIG. 2 is a schematic view of the server computer set 100 of FIG. 1 which further includes a control module 102.

As shown in FIG. 2, the server computer set 100 further includes the control module 102, and the control module may include a first control unit 102a and plural second control units 102b. The first control unit 102a is coupled respectively to the first battery backup module 160 and the power cabinet 120. The second control units 102a are coupled to the second battery backup module 180.

The first control unit 102a is coupled to the power cabinet 120 and the first battery backup module 160. When the external power source 200 or the high-voltage DC power HVD generated by the power cabinet 120 is abnormal, the first control unit 102a in the control module 102 triggers the first battery backup module 160 to generate and provide a backup high-voltage DC power, so as to drive the system cabinets 140 to operate normally or perform an urgent data retention function.

When the high-voltage DC power HVD generated by the power cabinet 120 is abnormal and the first battery backup module 160 has an insufficient backup electric quantity, the second control units 102b of the control module 102 in this embodiment can trigger the second battery backup module 180, and the second battery backup module 180 can generate a backup low-voltage DC power and supply it to the internal circuits in the system cabinets 140 for use.

In an actual application, the first control unit 102a and the second control units 102b can be integrated into a single circuit controller, or the first control unit 102a and the second control units 102b can be divided into circuit control elements to be disposed respectively in the first battery backup module or the second battery backup module. This invention is not limited to this. For example, the second control unit 102b can be further divided into plural second control subunits (not shown), and each second control subunit is disposed on a second battery backup unit 182.

Through the above double-layer backup architecture (the first battery backup module 160 and the second battery backup module 180), the first backup time and the second backup time can be aggregated, thereby forming a longer backup time equivalently, thus increasing the availability of the backup power, further improving the stability of the server computer set 100.

In sum, this invention provides a server computer set, wherein a high-voltage DC power is transmitted directly between a power cabinet and a system cabinet of the server computer set. Therefore, a DC battery backup module can be used directly to provide a backup power. Thus, a step of converting an AC power into a DC power for backup can be omitted (in that step; an AC-DC converter needs to be disposed), and a step of converting the DC backup power back into the AC power for use can also be omitted (in that step, a DC-AC converter needs to be disposed). In addition, the battery backup module can be distributed to each system cabinet, without occupying a large space around the power cabinet. Moreover, in this invention, a first-layer battery backup unit (BBU) is disposed between the power cabinet and the system cabinet, and a second-layer battery backup unit is additionally disposed in a system unit. By disposing the double-layer battery backup units, an effective backup time can be prolonged, and the availability of the backup power is increased, thereby improving the stability of the server computer set.

Although this invention has been disclosed with reference to the above embodiments, these embodiments are not intended to limit this invention. It will be apparent to those skilled in the art that various modifications and variations can be made without departing from the scope or spirit of this invention. Therefore, the scope of this invention shall be defined by the appended claims.

What is claimed is:

1. A server computer set, comprising:
a power cabinet coupled to an external power source for converting a high-voltage alternating current (AC) power supplied by the external power source into a high-voltage direct current (DC) power;
at least one system cabinet coupled to the power cabinet, wherein the system cabinet comprises a plurality of system units, the system cabinet shunting the high-voltage DC power to the system units, each system unit comprising a transformer and an internal circuit, wherein the transformer is used for transforming the high-voltage DC power to a low-voltage DC power, and the low-voltage DC power is used for driving the internal circuit;
a first battery backup module coupled between the power cabinet and the system units for providing a backup high-voltage DC power; and
a second battery backup module comprising a plurality of second battery backup units each of which is disposed in one of the system units and is coupled between the transformer and the internal circuit in the one of the system units for providing a backup low-voltage DC power.

2. The server computer set of claim 1, wherein the first battery backup module comprises a lithium ion battery unit.

3. The server computer set of claim 1, wherein the first battery backup module comprises a lead acid battery unit.

4. The server computer set of claim 1, wherein the second battery backup module comprises a lithium ion battery unit.

5. The server computer set of claim 1, further comprising a control module coupled respectively to the power cabinet and the first battery backup module, wherein, when the external power source is abnormal or the high-voltage DC power generated by the power cabinet is abnormal, the control module triggers the first battery backup module to supply the backup high-voltage DC power.

6. The server computer set of claim 5, wherein the first battery backup module stores a first electric quantity therein, and the first electric quantity corresponds to a first backup time.

7. The server computer set of claim 5, wherein the control module is further coupled to the second battery backup module, and when the external power source is abnormal or the high-voltage DC power generated by the power cabinet is abnormal and the first battery backup module has an insufficient electric quantity, the control module triggers the second battery backup module to supply the backup low-voltage DC power.

8. The server computer set of claim 7, wherein the second battery backup module stores a second electric quantity therein, and the second electric quantity corresponds to a second backup time.

9. The server computer set of claim 1, wherein the first battery backup module comprises at least one first battery backup unit, and the at least one first battery backup unit is disposed between the power cabinet and the at least one system cabinet.
